(19) United States
(12) Patent Application Publication
(10) Pub. No.: US 2009/0179677 A1
(43) Pub. Date: Jul. 16, 2009

(54) CIRCUIT FOR GENERATING OVERLAPPING SIGNALS

(75) Inventor: Marcin Augustyniak, Freising (DE)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/874,050

(22) Filed: Oct. 17, 2007

Related U.S. Application Data
(60) Provisional application No. 60/882,468, filed on Dec. 28, 2006.

(30) Foreign Application Priority Data
Oct. 18, 2006 (DE) 102006049233.1

(51) Int. Cl. H03K 5/01; H03H 11/26

(52) U.S. Cl. 327/165; 327/271

(57) ABSTRACT

A circuit for generating overlapping signals from a single input signal includes a pair of complementary MOS transistors. The complementary MOS transistors have interconnected gates and are connected in series between opposite supply terminals by a chain of successive reciprocal delay stages. The input signal is applied to the interconnected gates, and the drains of the MOS transistors and taps between successive delay stages each form a node that provides one of the overlapping signals.

### FIELD OF THE INVENTION

The present invention generally relates to a circuit for generating overlapping signals. More particularly, the invention relates to a circuit for generating a family of overlapping signals from a single control signal.

### BACKGROUND OF THE INVENTION

In specific applications it is required to have several overlapping signals for controlling different components in integrated circuits. In order to generate the signals from a single control signal, a conventional approach requires complex circuitry with many digital gates.

The present invention has been devised with the foregoing in mind.

### SUMMARY OF THE INVENTION

Thus the present invention provides a circuit for generating overlapping signals from a single input signal. The circuit comprises a pair of complementary MOS transistors with interconnected gates. The pair of transistors are connected in series between opposite supply terminals by a chain of successive reciprocal delay stages. Because the circuit is employed in CMOS technology with a single delay chain, it does not take up much space on a chip.

The delay chain can be implemented as a simple RC delay chain, where each delay stage is formed by a capacitive element and a resistive element. The delay chain can alternatively be configured so that each of the delay stages comprises a transmission gate, for example a pair of complementary MOS transistors. Each transmission gate is then connected between neighbouring nodes.

Pulse shaping circuitry is preferably employed to reshape the edges of the generated signals at the signal output. This is because the output signals get distorted by RC filtering in a delay line where each delay element just includes a resistor and a capacitor. The pulse shaping circuitry can comprise an inverter (or two inverters connected in series) connected to each node. Preferably the delay stages all have the same delay. The signal produced by the first delay element (the delay element closest to the control signal input) has its rising edge occurring before and its falling edge occurring after those of the signal generated by the neighbouring delay element further along the delay chain.

### BRIEF DESCRIPTION OF THE DRAWINGS

Further advantages and characteristics ensue from the description below of the preferred embodiments, and from the accompanying drawings, in which:

FIG. 1 is a circuit for generating overlapping signals according to a first embodiment of the invention;

FIG. 2 is a circuit for generating overlapping signals according to a second embodiment of the invention; and

FIG. 3 is a diagram of overlapping signals generated by a circuit according to the invention.

### DETAILED DESCRIPTION

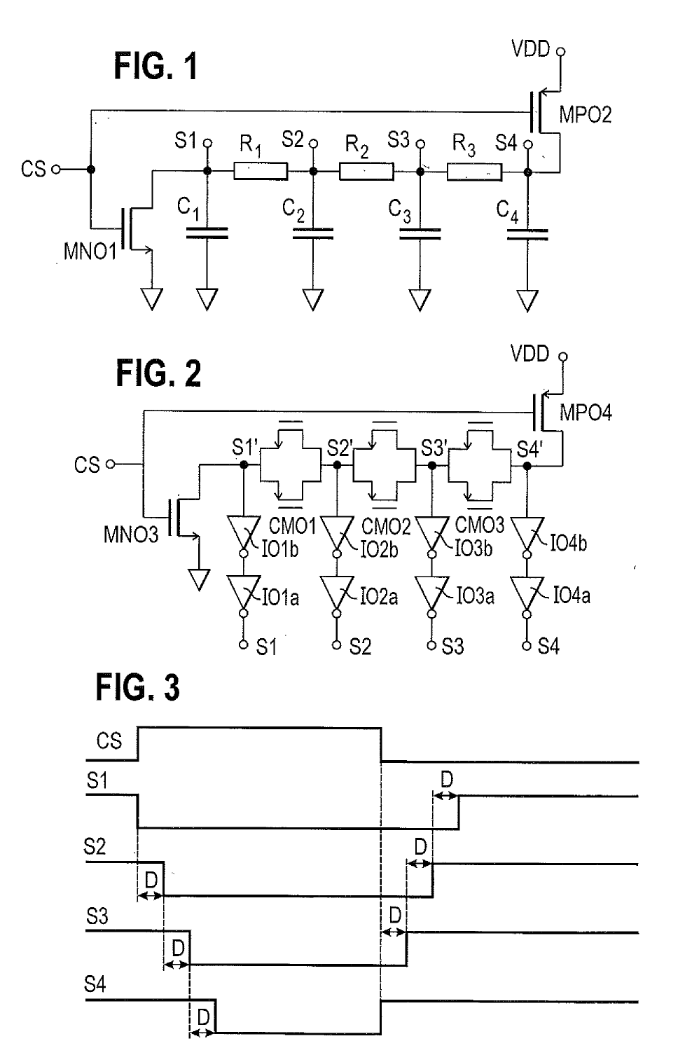

FIG. 1 shows a circuit for generating overlapping signals. An input operable to receive a control signal CS is connected to the gate of an n-type MOS transistor MN01 and also to the gate of a p-type MOS transistor MP02. The gates of the transistors MN01 and MP02 are interconnected. Resistors R1, R2 and R3 are connected in series between the source of the n-type transistor MN01 and the source of the p-type transistor MP02. A voltage input terminal VDD connected to the source of the p-type transistor MP02. The source of the n-type transistor MN01 is connected to ground.

Capacitors C1, C2, C3 and C4 each have an electrode connected to a node on the line connected between the drains of the transistors MN01 and MP02, such that one electrode of each of the capacitors C1, C2, C3 and C4 is alternately connected in series with the resistors R1, R2, R3 and R4. That is, C1 is associated with R1, C2 is associated with R2 etc. The capacitors C1, C2, C3 and C4 each have their other electrode connected to ground. Each resistance-capacitance pair R1C1, R2C2 etc forms a delay stage so that the delay stages connected together form a delay chain. Only the final capacitor C4 in the chain (the capacitor closest to the second transistor MP02 and furthest away from the input for the control signal CS) does not have an associated resistor. Although four delay stages are shown here, it is possible to have as many stages in the delay line as required. In the embodiment shown, the number of resistors will be one less than the number of capacitors in the chain.

Signal output taps S1, S2, S3 and S4 are provided at the nodes where the capacitors C1, C2, C3 and C4, respectively, are connected to the delay line. The signal output taps S1, S2, S3 and S4 are operable to output signals based on the control signal CS.

When an input signal CS is applied to the gates of each of the transistors MN01 and MP02, the resultant signals generated by the circuit in FIG. 1 are shown schematically in FIG. 3. The rising edge of the control signal CS applied to the gate of the transistor MN01 triggers a low signal to appear at the output tap S1, which propagates along the delay chain and the falling edge of the control signal CS applied to the gate of the transistor MP02 triggers a high signal to appear at the output tap S4, which propagates along the delay chain in the opposite direction. After a delay D, a low signal appears at the output tap S2 and so on, as the signal propagates down the delay line and reaches the last tap S4. The falling edge of the signal then triggers the signal output from the tap S4 to go high, then after a delay D triggers the signal output from the tap S3 to go high and so on up to the output tap S1. Each of the signals output from the taps S1-S4 has an inverse polarity to the input signal CS.

In reality, the edges of the signals produced at the output taps S1, S2, S3 and S4 can be distorted by RC filtering at the resistors and capacitors in the circuit. This means that a pulse shaping circuit should be employed at each delay stage following the nodes so as to correct the distorted output signals. However, in a circuit according to the second embodiment of the invention, shown in FIG. 2, each delay stage inherently performs pulse shaping of the output signals.

As described above with reference to the first embodiment, the circuit shown in FIG. 2 comprises an n-type MOS transistor MN03 with a gate connected to the gate of a p-type MOS transistor MP04. An input terminal operable to receive an input signal CS is connected to a node on the line interconnecting the gates of the of the transistors MN03 and MP04. Again a delay chain having four delay stages is connected between the drain of the n-type transistor and the drain of the p-type transistor. However, in this embodiment, the resistors R1-R3 and the capacitors C1-C4 are replaced by transmission gates formed from CMOS transistors CM01, CM02 and CM03. In addition, each node S1′-S4′ is followed by two inverters I01a, I01b; I02a, I02b; I03a, I03b; and I04a, I04b, respectively, to enable the output nodes S1-S4 to drive a higher load. In this embodiment, the resistive and capacitive elements of the delay line are distributed over the integrated circuit that implements the MOS transistors and transmission gates. The output signals at nodes S1-S4 look like the generated signals shown in FIG. 3 and do not require further pulse-shaping.

Thus the present invention provides the advantage of a circuit for generating a family of overlapping signals, which is low in complexity and does not consume much area on an integrated circuit.

Although the present invention has been described with reference to specific embodiments, it is not limited to these embodiments and no doubt further alternatives will occur to the skilled person that lie within the scope of the invention as claimed.

For example, the polarities of the complementary MOS transistors in the circuit can be reversed.

1. A circuit for generating overlapping signals from a single input signal, comprising a pair of complementary MOS transistors with interconnected gates and connected in series between opposite supply terminals by a chain of successive reciprocal delay stages, wherein the input signal is applied to the interconnected gates, and wherein the drains of said MOS transistors and taps between successive delay stages each form a node that provides one of said overlapping signals.

2. The circuit according to claim 1, wherein the delay stages are each formed by a capacitive element and a resistive element.

3. The circuit according to claim 1, wherein the delay stages are each formed by a transmission gate composed of a pair of complementary MOS transistors.

4. The circuit according to claim 1, wherein said nodes are followed by pulse shaping circuitry.

5. The circuit according to claim 4, wherein said pulse shaping circuitry comprises an inverter or a series connection of two inverters connected to each node.

6. The circuit according to claim 1, wherein said delay stages all have the same delay.

7. The circuit according to claim 2, wherein said nodes are followed by pulse shaping circuitry.

8. The circuit according to claim 3, wherein said nodes are followed by pulse shaping circuitry.

9. The circuit according to claim 2, wherein said delay stages all have the same delay.

10. The circuit according to claim 3, wherein said delay stages all have the same delay.

11. The circuit according to claim 4, wherein said delay stages all have the same delay.

12. The circuit according to claim 5, wherein said delay stages all have the same delay.

13. A circuit for generating overlapping signals from a single input signal, comprising a pair of complementary MOS transistors with interconnected gates and connected in series between opposite supply terminals by a chain of successive reciprocal delay stages, wherein the input signal is applied to the interconnected gates, and wherein the channels of said MOS transistors and taps between successive delay stages each form a node that provides one of said overlapping signals.

14. The circuit according to claim 13, wherein the delay stages are each formed by a capacitive element and a resistive element.

15. The circuit according to claim 13, wherein the delay stages are each formed by a transmission gate composed of a pair of complementary MOS transistors.

16. The circuit according to claim 13, wherein said nodes are followed by pulse shaping circuitry.

17. The circuit according to claim 16, wherein said pulse shaping circuitry comprises an inverter or a series connection of two inverters connected to each node.

18. The circuit according to claim 13, wherein said delay stages all have the same delay.

19. The circuit according to claim 14, wherein said nodes are followed by pulse shaping circuitry.

20. The circuit according to claim 15, wherein said nodes are followed by pulse shaping circuitry.
